(19) United States
(12) Patent Application Publication
(10) Pub. No.: US 2025/0341563 A1
(43) Pub. Date: Nov. 6, 2025

(54) MOBILE DEVICE FOR FIXING TEST BOARD

(71) Applicant: Hosin Global Electronics Co., LTD, Shenzhen (CN)

(72) Inventors: Kelvin Lam, Shenzhen (CN); Hangqi Guo, Shenzhen (CN); Yuewen Zhou, Shenzhen (CN); Yawen Zhuang, Shenzhen (CN)

(21) Appl. No.: 19/266,285

(22) Filed: Jul. 11, 2025

(30) Foreign Application Priority Data
Sep. 6, 2024 (CN) 2024112497930

(51) Int. Cl. G01R 31/28

(52) U.S. Cl. CPC G01R 31/2867

(57) ABSTRACT

The present disclosure relates to a mobile device for fixing a test board, comprising a frame, the frame including sliding regions, moving components, movable rods and resettable components. The movable rods are disposed on the frame and configured to limit a free surface arranged on one side of the frame. Each of the resettable components includes a reset member and a limiting plate, the reset member being fixedly disposed in the sliding region and fixedly connected to the limiting plate. Each of the resettable components is located at a first position to limit a test board in the sliding region.

### CROSS-REFERENCE TO RELATED APPLICATIONS

This application claims the priority benefit of China application serial no. 202411249793.0, filed on Sep. 6, 2024. The entirety of the abovementioned patent application is hereby incorporated by reference herein and made a part of this specification.

### TECHNICAL FIELD

The present disclosure relates to the technical field of chip testing, and more particularly to a mobile device for fixing a test board.

### BACKGROUND

The aging test of chips is one of the critical means for evaluating performance degradation in semiconductor chips under prolonged operation conditions. With the widespread application of electronic devices and the increasing complexity of integrated circuits, the reliability and service life of chips have become pivotal factors influencing the product quality and market competitiveness.

During chip testing, the test boards are subjected to the aging test within an aging chamber. Due to the substantial size and quantity of the test boards, a carrier cart is employed to carry and transport them. The test boards are moved into the chamber and inserted into its designated slots for the aging test.

In the current configuration, one side of the carrier cart is a free surface designed to allow the test boards to slide out for insertion into the slots within the chamber prior to testing, facilitating cart withdrawal before test initiation. However, during transportation, uneven road surfaces or excessive movement speed may cause the test boards to accidentally fall from the free surface of the cart.

### SUMMARY

The technical problem to be solved by the present disclosure is that during the transportation of the test board on a carrier cart, when the road surface is uneven or the moving speed is too fast, the test board is liable to slide off from the free end. In view of the above defects of the prior art, a mobile device for fixing a test board is provided.

The technical solution adopted by the present disclosure to solve the technical problem is as follows:

A mobile device for fixing a test board is provided, comprising a frame, the frame including sliding regions and moving components, the sliding regions and the moving components being disposed on the frame, and characterized by comprising: movable rods and resettable components; wherein the movable rods are disposed on the frame and configured to limit a free surface arranged on one side of the frame; each of the resettable components includes a reset member and a limiting plate, the reset member being fixedly disposed in the sliding region and fixedly connected to the limiting plate; wherein each of the resettable components is located at a first position to limit a test board in the sliding region.

In some embodiments, the mobile device comprises a box body, wherein the box body includes a plurality of ejector rods, the ejector rods are arranged corresponding to the resettable components, respectively, the box body is provided with a plurality of slots, and the slots are arranged corresponding to the sliding regions, respectively.

In some embodiments, when the ejector rod does not abut against the limiting plate, the resettable component is located at the first position; when the ejector rod abuts against the limiting plate, the resettable component is located at a second position; wherein the resettable component is located at the second position to make the test board slide to the box body.

In some embodiments, a length of the ejector rod is greater than or equal to a length of the test board inserted into the slot.

In some embodiments, each of the sliding regions is provided with a groove, the reset member is fixed in the groove, and the reset member is fixedly connected to the limiting plate.

In some embodiments, the reset member is fixedly disposed in the groove, wherein: the groove is provided with a plurality of fixing holes and fixing columns and located on a side close to the box body; the reset member is provided with a plurality of mounting columns, protrusion portions and deformation portions; the mounting columns are respectively embedded in the corresponding fixing holes, and the protrusion portions are provided below the deformation portion; the limiting plate is provided with a notch corresponding to each of the protrusion portions, the protrusion portion is fixedly disposed in the notch, and the limiting plate is provided with an arc groove corresponding to the deformation portion, the deformation portion is disposed in the arc groove and sleeves an outer side of the fixing column.

In some embodiments, when the ejector rod does not abut against the limiting plate, the protrusion portion is vertically disposed in the notch, and the protrusion portion and the limiting plate are located at a first position; when the ejection rod abuts against the limiting plate, the limiting plate drives the deformation portion to rotate around the fixing column in the arc groove until the limiting plate and the protrusion portion are located at a second position; when the limiting plate is located at the second position, a free end of the limiting plate faces the free surface.

In some embodiments, two ends of the protrusion portion are provided with a fixing structure, respectively, the notch of the limiting plate is provided with a fixing groove corresponding to the fixing structure; and the fixing structure is disposed in the corresponding fixing groove, respectively.

In some embodiments, the protrusion portion is provided with a first through hole, and a second through hole corresponding to the first through hole and a fixing pin are provided on two sides of the notch, and the fixing pin is provided in the first through hole and the second through hole.

In some embodiments, the frame is provided with corresponding sliding structures, and each pair of corresponding sliding structures constitutes one sliding region.

In some embodiments, a locking structure is provided in the sliding structure, the locking structure is arranged corresponding to the limiting plate located at the second position, and the locking structure is configured to unlock and fix the limiting plate located at the second position; wherein the limiting plate is provided with an inclined surface, the locking structure is provided with a slope, and the slope is against or away from the inclined surface.

In some embodiments, a concave portion is provided on a lower surface of the limiting plate, a fixing portion is provided in the concave portion, and the fixing portion is configured to fix at least one roller.

The beneficial effects of the present disclosure are as follows: the movable rods and the free surface are provided on the frame, and after the test board is placed on the frame, the movable rods can limit the free surface, the resettable components are provided in the sliding region, and when the resettable components are located at the first position, the test board in the moving region can be limited to prevent the test board from sliding out of the moving region when encountering an uneven road surface or moving too fast during transportation by the moving components. At the same time, since the reset member provided in the resettable component can reset, it rotates after being acted upon by an external force until the resettable component is located at the second position, so that the test board can slide from the sliding region into the box body for testing, and after the frame is pulled out of the box body, it can reset, which is convenient for the subsequent transportation of the test board and limit the test board again.

### BRIEF DESCRIPTION OF DRAWINGS

In order to more clearly illustrate the embodiments of the present disclosure or the technical solutions in the prior art, the present disclosure will be further described below in conjunction with the accompanying drawings and embodiments. The drawings described below are only some embodiments of the present disclosure. For those having ordinary skills in the art, other drawings can be obtained based on these drawings without creative work:

FIG. 1 is an overall structural diagram of a mobile device for fixing a test board according to one embodiment of the present disclosure;

FIG. 2 is a schematic diagram showing a front view of a mobile device for fixing a test board according to one embodiment of the present disclosure;

FIG. 3 is a schematic cross-sectional view of an A-A portion of FIG. 2 of the present disclosure;

FIG. 4 is a schematic diagram showing a partial enlargement of a section I in FIG. 2 of the present disclosure;

FIG. 5 is a schematic diagram showing a front view of a resettable component located at a second position according to one embodiment of the present disclosure;

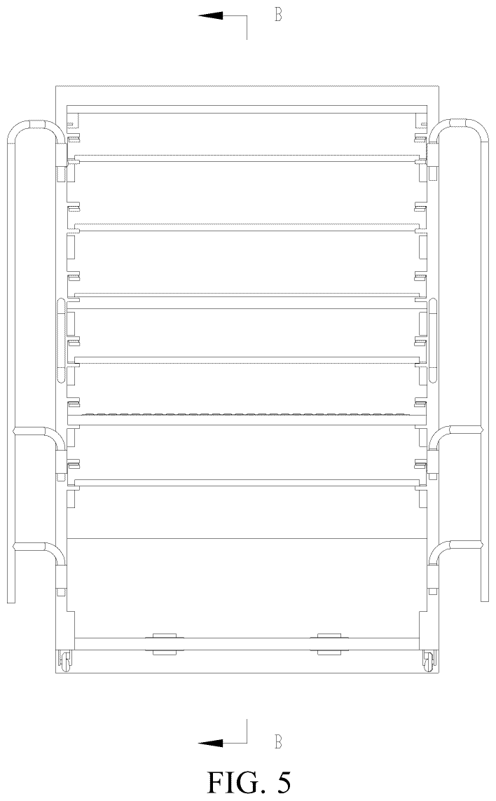

FIG. 6 is a schematic cross-sectional view of a section B-B in FIG. 5 of the present disclosure;

FIG. 7 is a three-dimensional schematic diagram of a box body according to one embodiment of the present disclosure;

FIG. 8 is a three-dimensional schematic diagram of a frame according to one embodiment of the present disclosure;

FIG. 9 is a schematic diagram showing a partial enlargement of a section Q in FIG. 8 of the present disclosure;

FIG. 10 is a three-dimensional schematic diagram of a reset member according to one embodiment of the present disclosure;

FIG. 11 is a three-dimensional schematic diagram of a limiting plate according to one embodiment of the present disclosure;

FIG. 12 is a schematic diagram showing a left view of a mobile device for fixing a test board according to one embodiment of the present disclosure;

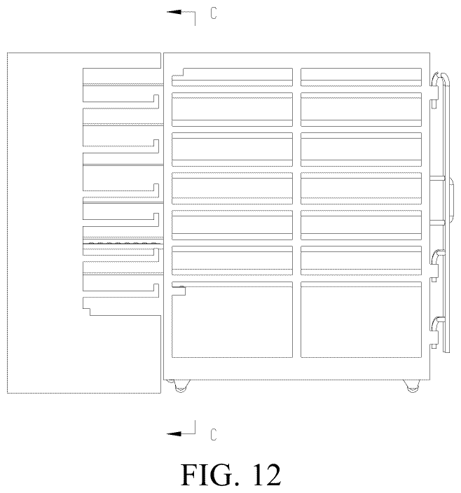

FIG. 13 is a schematic cross-sectional view of a section C-C of FIG. 12 of the present disclosure;

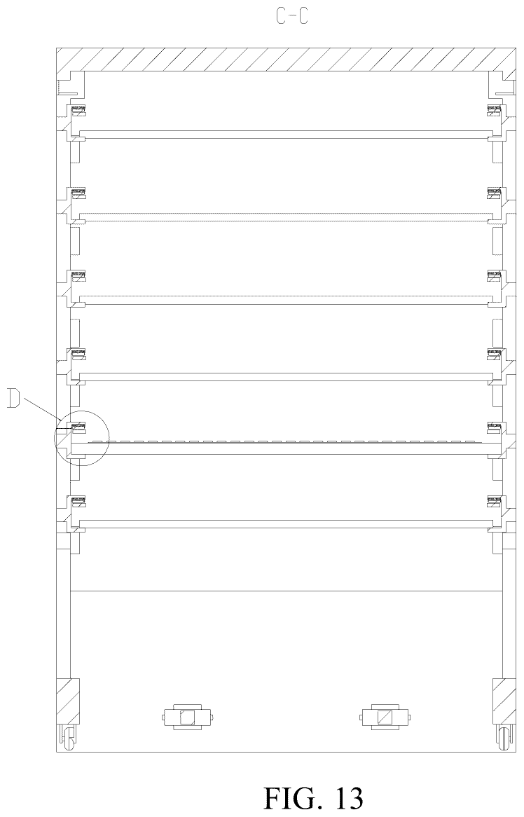

FIG. 14 is a schematic diagram showing a partial enlargement of a section D in FIG. 13 of the present disclosure;

FIG. 15 is a three-dimensional schematic diagram of a box body according to one embodiment of the present disclosure;

FIG. 16 is a schematic diagram showing a front view of a limiting plate according to one embodiment of the present disclosure;

FIG. 17 is a schematic cross-sectional view of a section E-E in FIG. 16 of the present disclosure.

Explanation of reference signs: frame 10, sliding region 11, moving component 12, movable rod 13, resettable component 14, first free surface 15, second free surface 16, reset member 141, limiting plate 142, box body 20, ejector rod 21, slot 22, groove 111, fixing hole 112, fixing column 113, mounting column 143, protrusion portion 144, notch 145, fixing structure 146, fixing groove 147, first through hole 148, fixing pin 149, second through hole 401, deformation portion 402, arc groove 403, sliding structure 17, rolling member 121, ball 101, elastic member 102, sleeve 103, fitting member 104, push rod 105, concave portion 201, fixing portion 202, roller 203.

### DETAILED DESCRIPTION

In order to make the purpose, technical solutions and advantages of the embodiments of the present disclosure clearer, the following will be described clearly and completely in combination with the technical solutions in the embodiments of the present disclosure. Obviously, the described embodiments are partial embodiments of the present disclosure, not all embodiments. Based on the embodiments of the present disclosure, all other embodiments obtained by those having ordinary skills in the art without creative work belong to the protection scope of the present disclosure.

The terms “first”, “second”, “third”, “fourth”, etc. (if any) in the specification and claims of the application and the above drawings are used to distinguish similar objects, and are not necessarily used to describe a specific order or sequence. It should be understood that the data used in this way can be interchangeable where appropriate, so that the embodiments described herein can be implemented in an order other than that illustrated or described herein. In addition, the terms “including” and “having” and any variations thereof are intended to cover non-exclusive inclusions, for example, a process, method, system, product or device that includes a series of steps or units is not necessarily limited to those steps or units clearly listed, but may include other steps or units that are not clearly listed or inherent to these processes, methods, products or devices.

The application is described in detail with reference to the schematic diagrams. When describing the embodiments of the application in detail, for the sake of convenience, the cross-sectional diagrams showing the device structure will not be partially enlarged according to the general scale, and the schematic diagrams are only examples, which should not limit the scope of protection claimed in the application. In addition, in actual production, the three-dimensional dimensions of length, width and depth should be included.

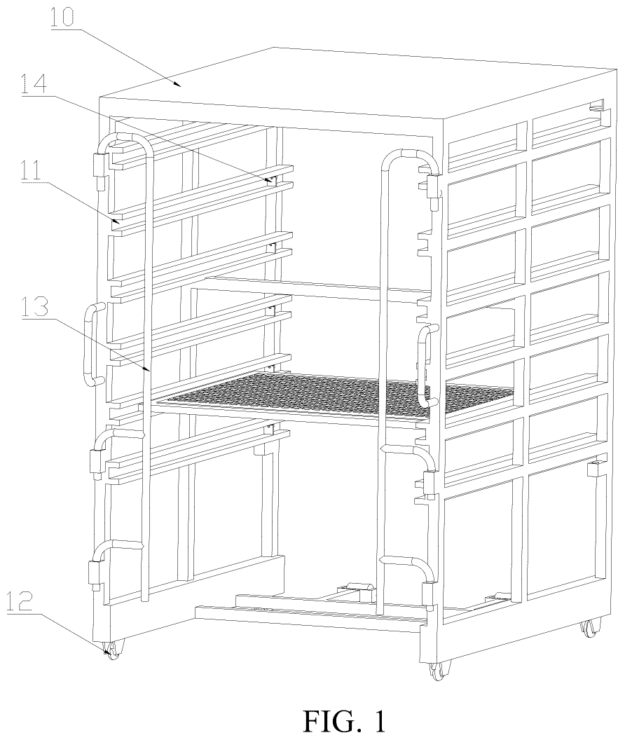

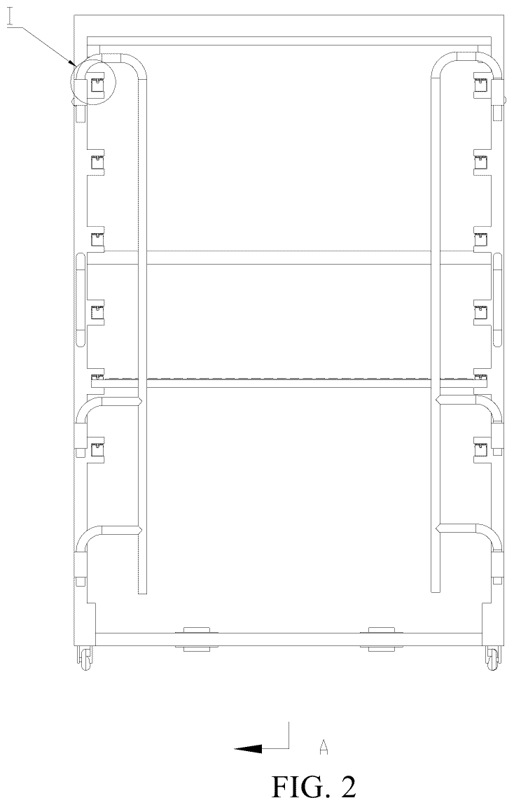

Please refer to FIGS. 1-4, one embodiment of the application provides a mobile device for fixing a test board to solve the above problem. The mobile device for fixing the test board provided in the application comprises a frame 10, the frame 10 including sliding regions 11, moving components 12, movable rods 13 and resettable components 14. The sliding regions 11 and the moving components 12 are respectively disposed on the frame 10, the movable rods 13 are disposed on the frame 10 and configured to limit a free surface arranged on one side of the frame 10. Each of the resettable component 14 includes a reset member 141 and a limiting plate 142. The reset member 141 is fixedly arranged in the sliding region 11, and is fixedly connected to the limiting plate 142; wherein the resettable component 14 is located at a first position to limit a test board in the sliding region 11. The application provides the movable rod 13 on the frame 10. After the test board is placed on the frame 10, the movable rod 13 can limit the free surface of the frame 10. The resettable component 14 is provided in the sliding region 11 to limit the test board in the sliding region 11 to prevent the test board from sliding off a sliding structure 17 when encountering an uneven road surface or moving too fast.

In order to make the above objectives, features and advantages of the application more obvious and easier to understand, the specific embodiments of the application are described in detail below with reference to the accompanying drawings.

As shown in FIGS. 1-4, in one embodiment, the frame 10 includes the sliding regions 11, the moving components 12, the movable rods 13, the resettable components 14, a first free surface 15 and a second free surface 16; wherein the sliding regions 11 and the moving components 12 are respectively disposed on the frame 10. Specifically, the sliding regions 11 are disposed on an inner side of the frame 10, and a length of the sliding region 11 is greater than a length of the test board, so that the test board has a movable space after being placed in the sliding region 11, and can slide in the sliding region 11. A space surface on one side of the frame 10 where the movable rod 13 is arranged is defined as the first free surface 15, and a space surface on the other side is defined as the second free surface 16. The movable rods 13 are disposed on one side of the frame 10, and limit the first free surface 15 of the frame 10. In a specific embodiment, two movable rods 13 are provided, and are respectively provided on two sides of the frame 10 to limit the first free surface 15 of the frame 10. In a specific embodiment, the movable rods 13 are movably provided on the frame 10, and after the test board is placed in the sliding region 11, the movable rods 13 are rotated so that the movable rods 13 are located on one side of the sliding region 11, and block the test board to prevent the it from sliding off the first free surface 15. In another embodiment, the first free surface 15 of the frame 10 is provided with a limiting groove, and a first free end of the movable rod 13 passes through the limiting groove, wherein a top end of the movable rod 13 is defined as a first free end, and the movable rod 13 can rotate around the frame 10; and a protrusion is provided on the first free end, the limiting groove includes a first limiting groove and a second limiting groove, and the protrusion is located in the first limiting groove or the second limiting groove, so that the movable rod 13 is in an open or closed state, making the frame 10 in a state of placing the test board or in a state of limiting the first free surface 15. The resettable component 14 limits the test board in the sliding region 11. The resettable component 14 includes a reset member 141 and a limiting plate 142. The reset member 141 is fixedly disposed on the sliding region 11 and is fixedly connected to the limiting plate 142; wherein the resettable component 14 is located at the first position to limit the test board in the sliding region 11.

Specifically, as shown in FIG. 1, the resettable component 14 is located at the first position for preventing the test board from sliding out and falling from the sliding region 11. The resettable component 14 includes the reset member 141 and the limiting plate 142. The reset member 141 is a torsion spring, and the limiting plate 142 is in the form of a sheet. The limiting plate 142 is in the form of a sheet and does not occupy the space in the sliding region 11 where the test board slides out, so that the test board can slide more smoothly from the sliding region 11 without getting stuck. The reset member 141 and the limiting plate 142 are arranged together in the sliding region 11, and the reset member 141 is fixedly connected to the limiting plate 142. In a specific embodiment, the limiting plate 142 and the reset member 141 are fixed by snapping. The limiting plate 142 is disposed in the sliding region 11, and when the resettable component 14 is located at the first position, the test board is limited. The horizontal movement direction of the test board is limited, thereby limiting the test board within the sliding region 11. In this way, the stability and safety of the test board during movement and operation are improved, preventing the test board from falling or being damaged.

In one embodiment, the frame 10 further includes a top plate, side frames and a bottom frame. The top plate is fixedly connected or detachably connected with the side frames, the sliding region 11 is disposed on the side frames, two side frames are provided and are symmetrically arranged below the top plate, and the test board is placed between the sliding regions 11 formed by the two side frames. The bottom frame is fixedly disposed at a bottom of the side frames and is provided with the moving component 12. In some embodiments, at least one cross bar is provided between the side frames to prevent the side frames from deforming.

In one embodiment, the application comprises a box body 20. The box body 20 includes a plurality of ejector rods 21 which are arranged corresponding to the resettable components 14, respectively, and the box body 20 is provided with a plurality of slots 22, and the slots 22 are arranged corresponding to the sliding regions 11, respectively.

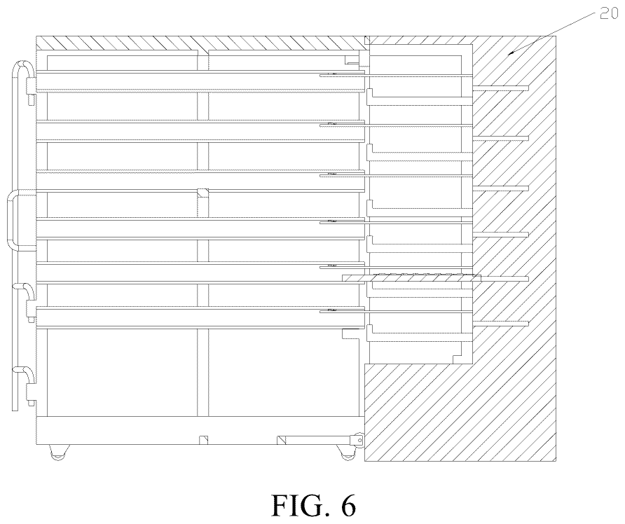

Specifically, as shown in FIG. 6, the plurality of ejector rods 21 are provided on a side of the box body 20 facing the frame 10, which are used for applying a force to the resettable components 14, so that the test board can slide out of the sliding region 11. The ejector rods 21 are made of a high temperature resistant material to avoid deformation after being subjected to a high temperature. The ejector rods 21 are arranged corresponding to the resettable components 14, respectively. In a specific embodiment, the resettable components 14 are arranged on any surface in the sliding region 11 and on two sides of the frame 10. The ejector rods 21 and the resettable component 14 are arranged correspondingly on two sides of the box body 20. The setting positions of the ejector rods 21 correspond to the limiting plates 142, so that after the frame 10 is close to the box body 20, the plurality of ejector rods 21 can contact the plurality of limiting plates 142, respectively, and push out the limiting plates 142. In a specific embodiment, the box 20 is a high temperature test box. When the frame 10 moves into the high temperature test box, since the high temperature test box is provided with the ejector rods 21, the ejector rods 21 apply a force to the resettable components 14 to make the resettable components 14 rotate.

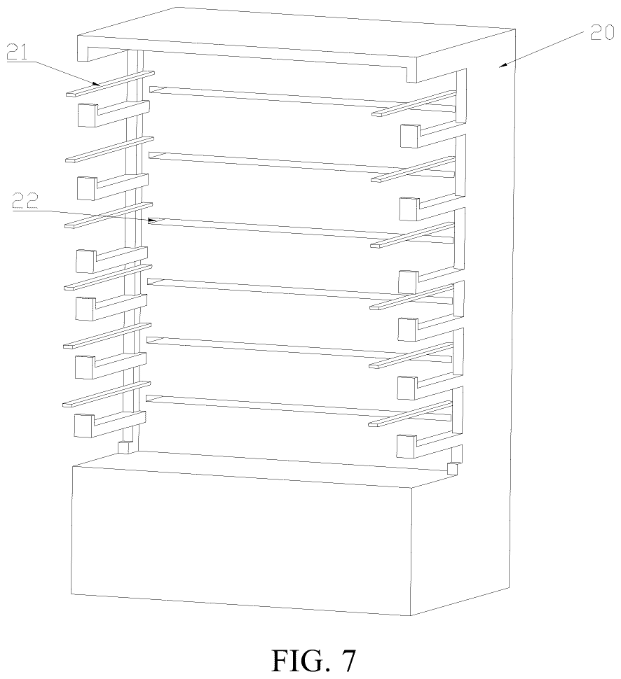

As shown in FIG. 7, the box 20 is provided with a plurality of slots 22, and the slots 22 are arranged corresponding to the sliding regions 11, so that the test board can slide from the sliding regions 11 to the slots 22 provided in the box body 20 for testing. In a specific embodiment, there are 6 slots 22, and the frame 10 is also provided with 6 test boards, which are arranged in the sliding regions 11. After the frame 10 moves to match the box body 20, the test boards in the sliding regions 11 are pushed into the slots 22 for testing.

In one embodiment, the resettable component 14 is located on an upper surface of the sliding regions 11. After the test board is placed in the sliding region 11, a free space between an upper surface of the test board and the sliding region 11, so as to prevent the resettable component 14 from affecting the test board from sliding out when it is located at the second position. If the resettable component 14 is located below or on a side of the sliding region 11, it causes resistance to the sliding out of the test board, affecting the sliding out of the test board.

In one embodiment, when the ejector rod 21 does not abut against the limiting plate 142, the resettable component 14 is located at the first position; when the ejector rod 21 abuts against the limiting plate 142, the resettable component 14 is located at the second position; the second position is used for making the test board slide to the box body 20.

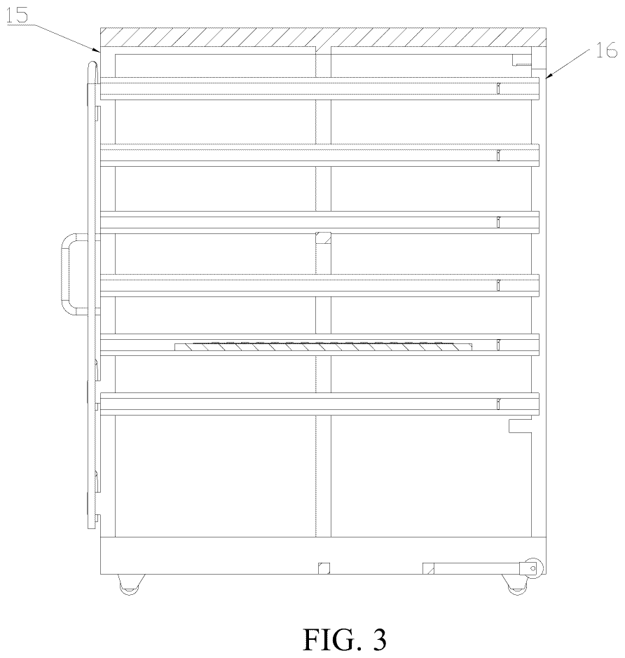

Specifically, as shown in FIG. 3 and FIG. 6, after an operator places the test board on the frame 10, the operator rotates the movable rod 13 to limit the free surface. At this time, the ejector rod 21 has not yet abutted against the limiting plate 142, the limiting plate 142 is placed vertically in the sliding region 11 and limits the test board to prevent the test board from sliding out. When the operator pushes the frame 10 to the box body 20, the ejector rod 21 in the box body 20 contacts and abuts against the limiting plate. At this time, the ejector rod 21 applies a thrust to the limiting plate 142, and the reset member 141 deforms after being subjected to the force and drives the limiting plate 142 to rotate until the limiting plate 142 and the reset member 141 are located at the second position. Then the operator pushes the test board into the slot 22 provided in the box body 20, and then pulls the frame 10 out of the box body 20 for testing. The limiting plate 142 is in the form of sheet, which can ensure that when the limiting plate 142 is located at the second position, it does not occupy the space in the sliding region 11.

In one embodiment, the length of the ejector rod 21 is greater than or equal to the length of the test board inserted into the slot 22.

Specifically, as shown in FIG. 6, when the frame 10 is pulled out from the box body 20, the ejector rod 21 can hold the resettable component 14 in the second position. Since the length of the ejector rod 21 is greater than the length of the test board inserted into the slot 22, after the frame 10 is separated from the box body 20, the resettable component 14 contacts the ejector rod 21, and then the resettable component 14 is completely separated from the ejector rod 21 to return to the first position. The length of the ejector rod 21 is greater than or equal to the length of the test board inserted into the slot 22, which can prevent the resettable component 14 from contacting the test board during the process of returning to the first position, and avoid the situation where the length of the ejector rod 21 is less than the length of the test board inserted into the slot 22, causing the resettable component 14 to press against the test board in the slot 22 during the process of returning to the first position to cause the test board to be scratched or displaced.

In one embodiment, the sliding region 11 is provided with a groove 111, the reset member 141 is fixedly disposed in the groove 111, and the reset member 141 is fixedly connected to the limiting plate 142.

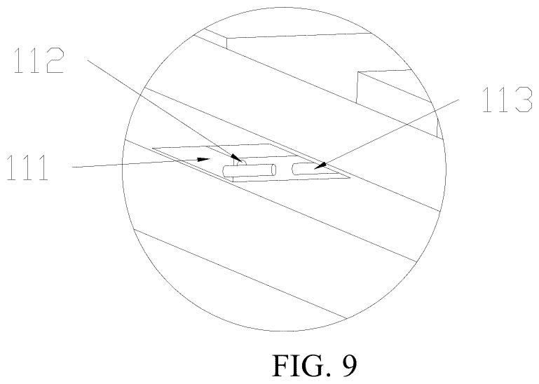

Specifically, as shown in FIG. 9, the groove 111 is provided in the sliding region 11, and the position of the groove 111 corresponds to the position of the limiting plate 142 (i.e., the upper surface, the lower surface or the side surface), and the groove 111 is provided in the sliding region 11. When the resettable component 14 is located at the second position, the reset member 141 and the limiting plate 142 can be placed in the groove 111 without occupying the space of the sliding region 11, so as to ensure that the test board can slide out of the sliding region 11. In a specific embodiment, the reset member 141 is fixedly connected to the limiting plate 142, and the limiting plate 142 is pushed into the groove 111 after being acted upon by an external force. During the movement of the limiting plate 142 toward the groove 111, the reset member 141 is deformed under the extrusion of the external force of the ejector rod 21.

In one embodiment, the reset member 141 is fixedly disposed in the groove 111, wherein: a plurality of fixing holes 112 and fixing columns 113 are provided in the groove 111, and are located on a side close to the box body 20; the reset member 141 includes a plurality of mounting columns 143, and the mounting columns 143 are embedded in the corresponding fixing holes 112, respectively; the reset member 141 is further provided with protrusion portions 144 and deformation portions 402, the protrusion proportions 144 are provided below the deformation portions 402, and the deformation portions 402 are fixedly connected to the protrusion portions 144; the limiting plate 142 is provided with a notch 145 corresponding to each of the protrusion portions 144, and the protrusion portion 144 is provided in the notch 145; the limiting plate 142 is provided with an arc groove 403 corresponding to the deformation portion 402, and the deformation portion 402 is provided in the arc groove 403, respectively, and sleeves an outer side of the fixing column 113.

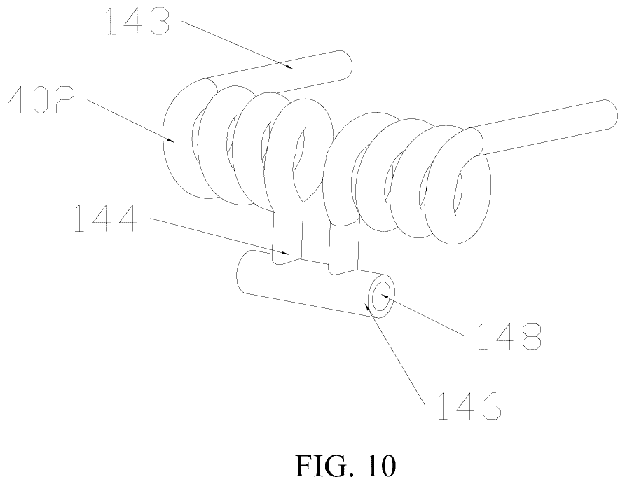

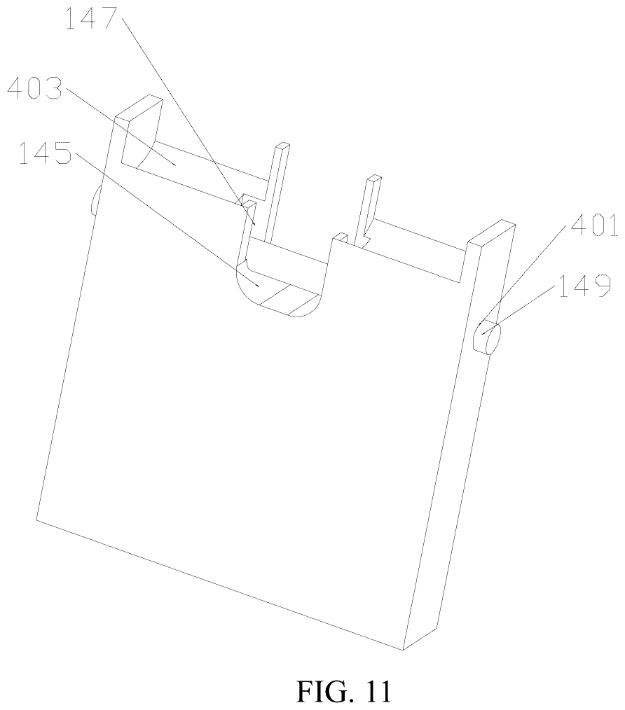

Specifically, as shown in FIG. 9 and FIG. 10, a plurality of fixing holes 112 are provided in the groove 111, and a plurality of mounting columns 143 are provided in the reset member 141. The fixing holes 112 are disposed near one side of the box body 20. In a specific embodiment, the groove 111 is provided with two fixing holes 112, and the reset member 141 is provided with two mounting columns 143, and the mounting columns 143 are embedded in the fixing holes 112. Fixing columns 113 are further provided in the groove 111, and the fixing columns 113 are arranged near one side of the box body 20 and arranged horizontally; the fixing holes 112 and the fixing columns 113 are arranged near one side of the box body 20, so that the ejection rod 21 can be placed in the groove 111 after ejecting out the limiting plate 142. In a specific embodiment, two fixing columns 113 are provided and arranged relatively in the groove 111, and the reset member 141 sleeves the outer side of the fixing columns 113, which allows the reset member 141 to deform in the groove 111 and rotate around the fixing columns 113. As shown in FIG. 10 and FIG. 11, during mounting, the protrusion portion 144 is placed in the notch 145, and the deformation portion 402 is placed in the arc groove 403. The arc groove 403 is arc-shaped and arranged corresponding to the deformation portion 402. A cross section of the deformation portion 402 is arc-shaped. The arc groove 403 is arc-shaped to prevent the limiting plate 142 from rubbing against the reset member 141 to cause damage during rotation. In a specific embodiment, the arc grooves 403 are arranged at a top of the limiting plate 142, and two arc grooves are provided. The reset member 141 is provided with two deformation portions 402 which are respectively arranged on both sides of the protrusion portion 144. After the protrusion portion 144 is placed in the notch 145 provided in the limiting plate 142, the deformation portions 402 are located in the arc grooves 403, respectively.

In one embodiment, when the ejection rod 21 does not abut against the limiting plate 142, the protrusion portion 144 is vertically arranged in the notch 145, and the protrusion portion 144 and the limiting plate 142 are located at the first position; when the ejection rod 21 abuts against the limiting plate 142, the limiting plate 142 drives the deformation portion 402 to rotate around the fixing column 113 in the arc groove 403 until the limiting plate 142 and the protrusion portion 144 are located at the second position; when the limiting plate 142 is located at the second position, the free end of the limiting plate 142 faces the side of the free surface.

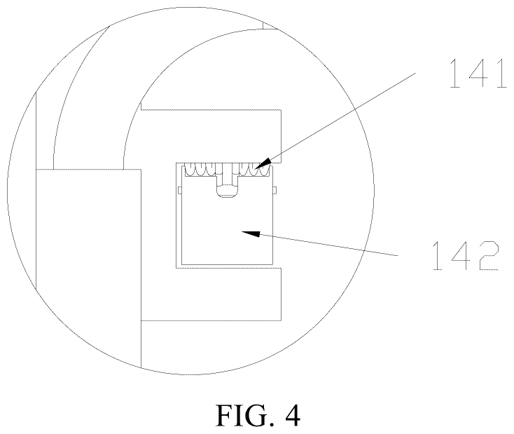

Specifically, as shown in FIG. 4, when the ejection rod 21 does not abut against the limiting plate 142, the reset member 141 and the limiting plate 142 are located at the first position, i.e., the reset member 141 is located at an initial position and has not yet been deformed, and the limiting plate 142 is vertically arranged in the sliding region 11, perpendicular to the moving direction of the test board. At this time, the limiting plate 142 limits the test board in the sliding region 11, intercepts the test board, and prevents the test board from sliding off the second free surface 16 of the frame 10. As shown in FIG. 6, when the operator pushes the frame 10 to the box body 20, the ejector rod 21 abuts against the limiting plate 142. At this time, the ejector rod 21 applies a thrust to the limiting plate 142. Under the action of the force, the reset member 141 is deformed. Since the limiting plate 142 is fixed to the protrusion portion 144, when the free end of the limiting plate 142 rotates toward the side of the free surface, it squeezes the reset member 141 and rotates together until the limiting plate 142 is located above the ejector rod 21 and in the groove 111, so that the test board can pass, and the second position is reached. At this time, the deformation portion 402 rotates around the fixing column 113 in the arc groove 403 until the limiting plate 142 is located in the groove 111, and an open region is formed between the ejection rod 21 and the sliding region 11, which enables the test board to slide from the sliding region 11 to the slot 22, so that the test board can pass and slide into the slot 22; wherein, the free end of the limiting plate 142 is an end of the limiting plate 142.

In one embodiment, a fixing structure 146 is disposed at two ends of the protrusion portion 144, respectively, and the notch 145 of the limiting plate 142 is provided with a fixing groove 147 corresponding to the fixing structures 146; the fixing structure 146 is disposed in the corresponding fixing groove 147, respectively.

Specifically, as shown in FIG. 10, the fixing structure 146 is provided at the two ends of the protrusion portion 144, respectively, and match with the limiting plate 142 to form fixation. In a specific embodiment, the fixing structure 146 is a column, i.e., the column is provided on the two sides of the protrusion portion 144, respectively, and the limiting plate 142 is provided with the fixing groove 147 corresponding to the column, and the column is placed in the fixing groove 147 to fix the reset member 141 and the limiting plate 142.

In another specific embodiment, a block is provided at two ends of the protrusion portion 144, respectively, and the block is provided with a through hole. The block is placed in the fixing grooves 147 provided on the limiting plate 142, and the limiting plate 142 is fixed to the reset member 141 by screws or screws passing through the through hole.

In one embodiment, the protrusion portion 144 is provided with a first through hole 148, and the two sides of the notch 145 are provided with a second through hole 401 corresponding to the first through hole 148 and a fixing pin 149, and the fixing pin 149 is disposed in the first through hole 148 and the second through hole 401.

Specifically, as shown in FIG. 10 and FIG. 11, the notch 145 is provided at a middle position of the top of the limiting plate 142, the protrusion portion 144 provided on the reset member 141 is placed in the notch 145 provided on the limiting plate 142, and the first through hole 148 is aligned with the second through hole 401, and then the fixing pin 149 penetrates into the first through hole 148 and the second through hole 401 to achieve the fixed connection between the reset member 141 and the limiting plate 142. In a specific embodiment, the fixing pin 149 is cylindrical, the first through hole 148 and the second through hole 401 are circular holes, and after the limiting plate 142 and the reset member 141 are fixed by the fixing pin 149, the limiting plate 142 can rotate around the reset member 141.

In one embodiment, the frame 10 is provided with corresponding sliding structures 17, and each pair of corresponding sliding structures 17 constitutes one sliding region 11.

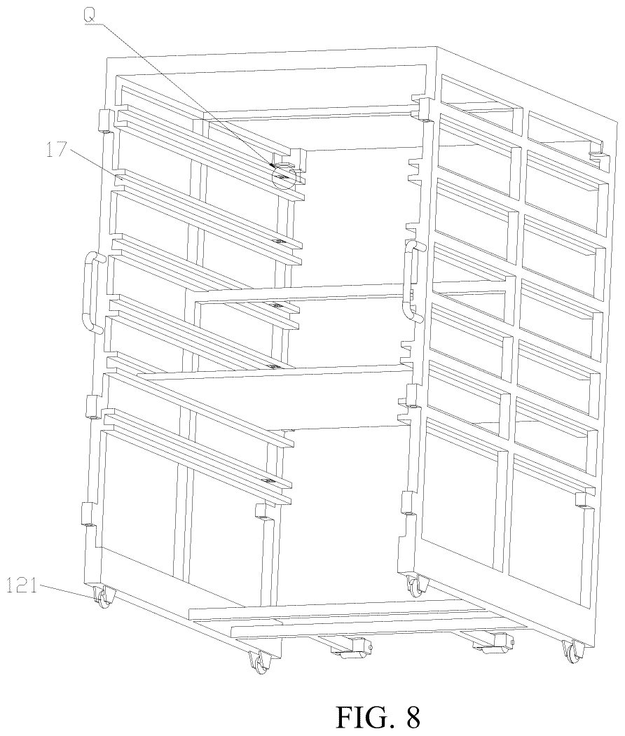

Specifically, as shown in FIG. 8, the corresponding sliding structures 17 are respectively provided on two sides of the frame 10, and the sliding structures 17 are sliding grooves. The sliding structures 17 corresponding to each other on two sides of the frame 10 form one sliding region 11, and the test board can be placed in the sliding region 11 and can slide in the sliding region 11. Accordingly, the sliding regions 11 are arranged corresponding to the slots 22 provided in the box body 20, so that all the test boards on the frame 10 can move from the sliding regions 11 to the slots 22.

In one embodiment, a locking structure is provided in the sliding structure 17, and the locking structure is arranged corresponding to the limiting plate 142 located at the second position, and the locking structure is configured to unlock and fix the limiting plate 142 located at the second position; wherein, the limiting plate 142 is provided with an inclined surface, and the locking structure is provided with a slope, and the slope is against or away from the inclined surface.

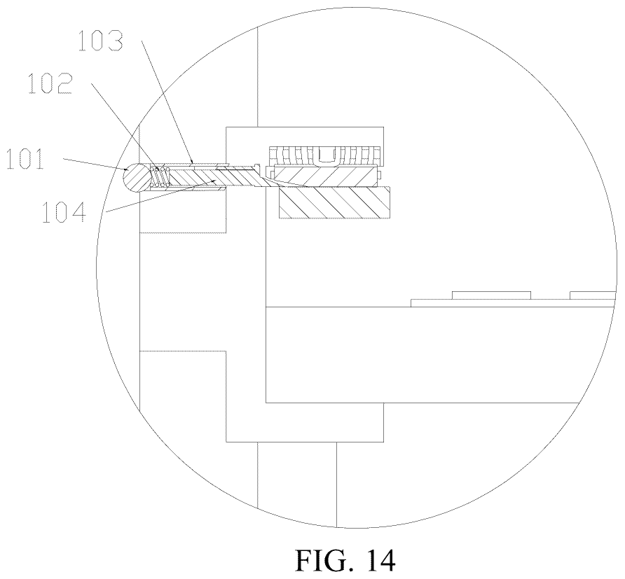

Specifically, as shown in FIG. 14, the locking structure includes a ball 101, an elastic member 102, a sleeve 103 and a fitting member 104. In a specific embodiment, the elastic member 102 is a spring; the ball 101 abuts against the elastic member 102, the sleeve 103 is sleeved on an outer side of the elastic member 102 and the fitting member 104, and the fitting member 104 abuts against the elastic member 102; when the ball 101 is squeezed, the elastic member 102 squeezes the fitting member 104 after being subjected to force, and then the slope provided on the fitting member 104 enters the inclined surface provided on the limiting plate 142 to bear the load on the limiting plate 142. At this time, the positions of the limiting plate 142 and the reset member 141 are slightly displaced, and the pressure applied to the ejector rod 21 by the limiting plate 142 is replaced by the locking structure or the pressure of the ejector rod 21 is shared, thereby preventing the ejector rod 21 from being deformed after being subjected to the downward force of the limiting plate 142 for a long time to ultimately fail to push the limiting plate 142 to the second position.

In another specific implementation, the locking structure includes the ball 101, the elastic member 102, the sleeve 103, a first fitting member, a second fitting member and a push block. The ball 101 abuts against the first fitting member, the first fitting member is provided with a first inclined groove, the second fitting member is provided with a second inclined groove and a strip-shaped slide bar, the first inclined groove and the second inclined groove are arranged correspondingly, the sleeve 103 is provided with an open groove corresponding to the slide bar, and an opening of the open groove faces the second fitting member; the sleeve is further provided with an inclined surface corresponding to the second inclined groove, the elastic member 102 abuts against the push block; the push block is provided with a slope corresponding to the inclined surface provided on the limiting plate 142. When a force is applied to the ball 101, the ball 101 applies pressure to the first fitting member, so that the first fitting member squeezes the second fitting member and the elastic member 102 that match it. At this time, the second fitting member moves forward and rotates at the same time. After the second fitting member rotates, the second inclined groove abuts against the inclined surface of the sleeve 103. At this time, due to the squeezing of the elastic member 102, the push block abutting against it moves forward, and the slope of the push block abuts against the inclined surface of the limiting plate 142. At this time, the pressure applied to the ejector rod 21 by the limiting plate 142 is converted to the locking structure. When the locking structure needs to be unlocked, the ball 101 is pressed again. At this time, the second fitting member rotates, and the slide bar of the second fitting member enters the open groove of the sleeve 103.

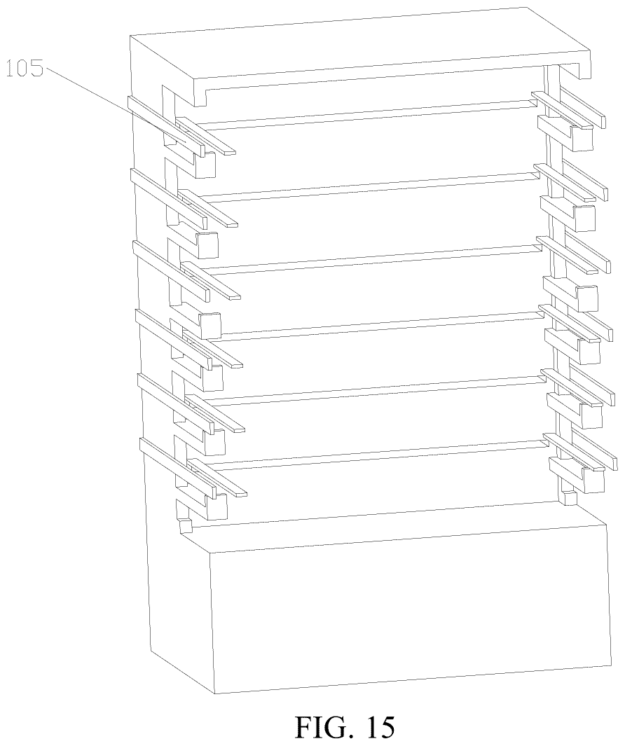

In one embodiment, the operator consumes a lot of time by locking or unlocking the above locking structure individually, affecting the work efficiency. As shown in FIG. 15, a plurality of push rods 105 are provided on an outer side of the box body 20, and the push rods 105 are arranged corresponding to the locking structure, and the push rods 105 are placed in a vertical direction, so as to facilitate pushing the ball 101 provided in the locking structure. A length of the push rod 105 is less than the length of the ejector rod 21. When the operator pushes the frame 10 to the box body 20, the ejector rod 21 first contacts the resettable component 14 and pushes the limiting plate 142 to the second position, and then the plurality of push rods 105 contact with the balls 101 provided in the plurality of locking structures and push the balls 101, so that the balls 101 squeeze the slopes or slope bodies to abut against the inclined surface provided by the limiting plate 142 and bear the pressure applied to the ejector rod 21 by the limiting plate 142, so as to achieve locking of the limiting plate 142, and then push the test board from the sliding region 11 to the box body 20. When the operator pulls the frame 10 out of the box 20, all the push rods 105 are away from the balls 101 at the same time. At this time, the slope body or the slope is away from the inclined surface provided by the limiting plate 142, so as to simultaneously unlock the limiting plates 142 provided on the plurality of resettable components 14. The plurality of push rods 105 can lock or unlock the locking structure at the same time, thereby locking or unlocking the limiting plate 142, which can greatly improve the work efficiency.

In one embodiment, when the resettable component 14 is disposed on the upper surface of the sliding region 11, the ejector rod 21 is subjected to a downward force after abutting against the resettable component 14, which may easily cause the ejector rod 21 to fall down after long-term use, making it impossible for the resettable component 14 to be located at the second position. To this end, the resettable components 14 are respectively disposed on the upper surface and the lower surface within the sliding region 11. At this time, the ejector rod 21 is subjected to the force of the resettable components 14 disposed on the upper surface and the lower surface, and is not easily deformed.

In one embodiment, a concave portion 201 is disposed on the lower surface of the limiting plate 142, a fixing portion 202 is disposed in the concave portion 201, and the fixing portion 202 is configured to fix at least one roller 203.

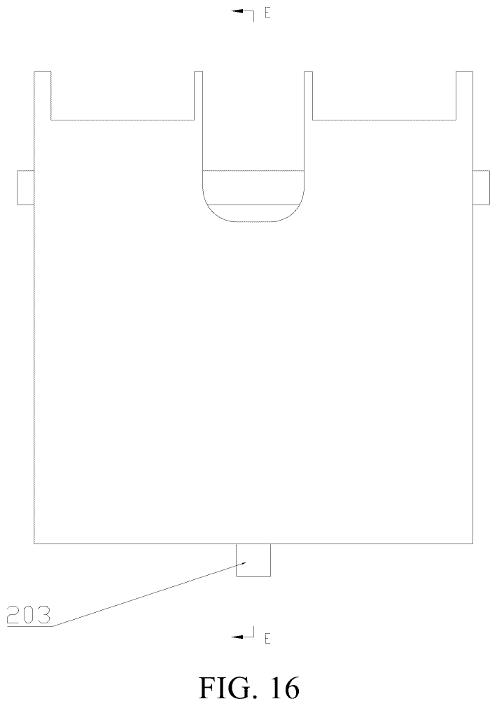

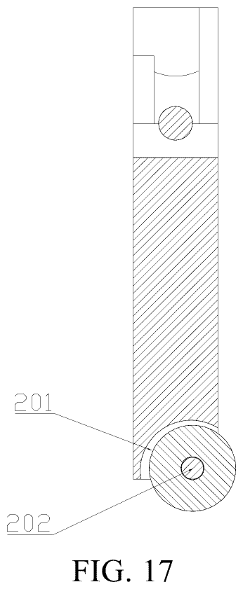

Specifically, as shown in FIG. 16 and FIG. 17, the concave portion 201 is provided on the lower surface of the limiting plate 142, the fixing portion 202 is provided in the concave portion 201, and the fixing portion 202 is provided with at least one roller 203. When the operator pushes the frame 10 into the box body 20, the ejection rod 21 can contact the roller 203 provided in the concave portion 201, and then the roller 203 rolls under the thrust of the ejection rod 21 and moves into the groove 111. The roller 203 provided on the lower surface of the limiting plate 142 can reduce the friction generated when the limiting plate 142 contacts the ejection rod 21, thereby avoiding wear of the ejection rod 21 or the limiting plate 142 after contacting, and improving the service life.

As shown in FIG. 8, specifically, the moving component 12 includes a plurality of rolling members 121, and the rolling members 121 are movably disposed at a bottom of the frame 10.

More specifically, the rolling members 121 are cylindrical and located at the bottom of the frame 10, and configured to drive the frame 10 to move. In a specific embodiment, the frame 10 is provided with a plurality of bottom frames, and the bottom frames are arranged toward a forward direction of the frame 10. Each of the rolling member 121 is provided with a through hole, the bottom frames are provided with columns corresponding to the through holes, and the columns respectively penetrate the through holes provided in the rolling member 121, so that the rolling members 121 are fixed on the frame 10 and can rotate. When the frame 10 is pushed, the rolling members 121 can be driven to rotate, thereby realizing the movement of the frame 10. In another specific embodiment, columns are provided at the bottom of the frame 10, and the rolling members 121 sleeve the columns and rotate with the push of the frame 10. In another specific embodiment, the rolling members 121 are universal wheels, which enable the frame 10 to move in multiple directions.

Each embodiment in this specification is described in a progressive manner, and the same or similar parts between the embodiments can be referred to each other, and each embodiment focuses on the differences from other embodiments. In particular, for the method embodiment, since it is basically similar to the structural embodiment, the description is relatively simple, and the relevant parts can be referred to the partial description of the structure embodiment.

The above is the specific embodiments of the application. It should be understood that the above embodiments are only used to illustrate the technical solution of the application, rather than to limit it; although the application is described in detail with reference to the above embodiments, those having ordinary skills in the art should understand that they can still modify the technical solutions recorded in the above embodiments, or replace some of the technical features therein by equivalents; and these modifications or replacements do not make the essence of the corresponding technical solutions deviate from the scope of the technical solutions of the embodiments of the application.

1. A mobile device for fixing a test board, comprising a frame, the frame including sliding regions and moving components, the sliding regions and the moving components being disposed on the frame, and characterized by comprising: movable rods and resettable components; wherein
the movable rods are disposed on the frame and configured to limit a free surface arranged on one side of the frame;
each of the resettable components includes a reset member and a limiting plate, the reset member being fixedly disposed in the sliding region and fixedly connected to the limiting plate; wherein each of the resettable components is located at a first position to limit a test board in the sliding region.

2. The mobile device according to claim 1, characterized by comprising a box body, wherein the box body includes a plurality of ejector rods, the ejector rods are arranged corresponding to the resettable components, respectively, the box body is provided with a plurality of slots, and the slots are arranged corresponding to the sliding regions, respectively.

3. The mobile device according to claim 2, characterized in that when the ejector rod does not abut against the limiting plate, the resettable component is located at the first position;
when the ejector rod abuts against the limiting plate, the resettable component is located at a second position; wherein the resettable component is located at the second position to make the test board slide to the box body.

4. The mobile device according to claim 2, characterized in that a length of the ejector rod is greater than or equal to a length of the test board inserted into the slot.

5. The moving device according to claim 2, characterized in that each of the sliding regions is provided with a groove, the reset member is fixed in the groove, and the reset member is fixedly connected to the limiting plate.

6. The mobile device according to claim 5, characterized in that the reset member is fixedly disposed in the groove, wherein:
the groove is provided with a plurality of fixing holes and fixing columns and located on a side close to the box body;
the reset member is provided with a plurality of mounting columns, protrusion portions and deformation portions;
the mounting columns are respectively embedded in the corresponding fixing holes, and the protrusion portions are provided below the deformation portion;
the limiting plate is provided with a notch corresponding to each of the protrusion portions, the protrusion portion is fixedly disposed in the notch, and the limiting plate is provided with an arc groove corresponding to the deformation portion, the deformation portion is disposed in the arc groove and sleeves an outer side of the fixing column.

7. The mobile device according to claim 6, characterized in that when the ejector rod does not abut against the limiting plate, the protrusion portion is vertically disposed in the notch, and the protrusion portion and the limiting plate are located at a first position;
when the ejection rod abuts against the limiting plate, the limiting plate drives the deformation portion to rotate around the fixing column in the arc groove until the limiting plate and the protrusion portion are located at a second position;
when the limiting plate is located at the second position, a free end of the limiting plate faces the free surface.

8. The mobile device according to claim 6, characterized in that two ends of the protrusion portion are provided with a fixing structure, respectively, the notch of the limiting plate is provided with a fixing groove corresponding to the fixing structure; and the fixing structure is disposed in the corresponding fixing groove, respectively.

9. The mobile device according to claim 6, characterized in that the protrusion portion is provided with a first through hole, and a second through hole corresponding to the first through hole and a fixing pin are provided on two sides of the notch, and the fixing pin is provided in the first through hole and the second through hole.

10. The mobile device according to claim 1, characterized in that the frame is provided with corresponding sliding structures, and each pair of corresponding sliding structures constitutes one sliding region.

11. The mobile device according to claim 10, characterized in that a locking structure is provided in the sliding structure, the locking structure is arranged corresponding to the limiting plate located at the second position, and the locking structure is configured to unlock and fix the limiting plate located at the second position; wherein
the limiting plate is provided with an inclined surface, the locking structure is provided with a slope, and the slope is against or away from the inclined surface.

12. The moving device according to claim 2, characterized in that a concave portion is provided on a lower surface of the limiting plate, a fixing portion is provided in the concave portion, and the fixing portion is configured to fix at least one roller.
